(19) United States
(12) Patent Application Publication
(10) Pub. No.: US 2023/0216510 A1
(43) Pub. Date: Jul. 6, 2023

(54) DUAL MODE PHASE LOOKED LOOP (PLL) FOR FREQUENCY-MODULATED CONTINUOUS WAVE (FMCW) RADAR

(71) Applicant: WISENSE TECHNOLOGIES LTD., Tel Aviv (IL)

(72) Inventor: RAN KRICHMAN KALINKA, Talmei Elazar (IL)

(73) Assignee: WISENSE TECHNOLOGIES LTD., Tel Aviv (IL)

(21) Appl. No.: 18/145,043

(22) Filed: Dec. 22, 2022

Related U.S. Application Data
(60) Provisional application No. 63/294,889, filed on Dec. 30, 2021.

(51) Int. Cl. H03L 7/099; H03L 7/093; G01S 7/35

(52) U.S. Cl. CPC H03L 7/099; H03L 7/093; G01S 7/354

(57) ABSTRACT

Embodiments of the invention may provide a phase locked loop (PLL) for a long-range and short-range frequency-modulated carrier-frequency (FMCW) RADAR system, including: a single feedback loop for generating a control signal based on differences between an output signal of the RADAR and a reference signal; a first voltage-controlled oscillator (VCO) adapted to generate a first output signal having a first loop bandwidth using the control signal; a second VCO adapted to generate a second output signal having a second loop bandwidth using the control signal; and an output switch for selecting one of the first output signal and the second output signal and outputting the selected signal as the output signal of the RADAR.

### CROSS REFERENCE TO RELATED APPLICATIONS

The present application claims the benefit of U.S. Provisional Application No. 63/294,889 filed on Dec. 30, 2021, incorporated herein by reference in its entirety.

### FIELD OF THE INVENTION

Embodiments of the present invention relate generally to the field of frequency-modulated continuous wave (FMCW) radio detection and ranging (RADAR) systems and more particularly to providing a dual mode phase looked loop (PLL) for such systems.

### BACKGROUND OF THE INVENTION

The use of radar systems is commonplace in modern applications of spatial navigation and location, such as in the emerging discipline of automated vehicles. Such systems are commonly required to provide high-end performance, to produce superior output signals for further analysis and manipulation.

Frequency-modulated continuous wave (FMCW) radar may radiate continuous transmission power that is modulated in frequency or in phase. The frequency of the transmitted signal may increase or decrease in time periodically or the phase may change with time. When an echo signal is received, the change of frequency or phase is delayed. The differences in phase or frequency between the transmitted and the received signals may be measured to detect the target range. Thus, FMCW radar may provide relatively accurate measurements of the target range and relative velocity.

Current FMCW RADAR systems are required to operate in two major modes of operations or ranges referred to as short-range (SR), e.g., 0-120 meters and long-range (LR) e.g., 120-300 meters. To operate well, SR and LR RADARs have very different and sometimes contradicting radio frequency (RF) requirements. One solution for supporting both SR and LR detection includes designing a single FMCW RADAR system that is a tradeoff between the two sets of requirements and therefore provides degraded functionality in both ranges. Another solution requires using two FMCW RADAR circuits and switching between the circuits. This solution provides good functionality in both ranges but requires large silicon size and external components and is therefore costly. Thus, a solution that would provide good functionality in both ranges in a lower cost is desired.

### SUMMARY OF THE INVENTION

According to embodiments of the invention, a phase locked loop (PLL) for a long-range and short-range frequency-modulated carrier-frequency (FMCW) RADAR system may include: a single feedback loop for generating a control signal based on differences between an output signal of the RADAR and a reference signal; a first voltage-controlled oscillator (VCO) adapted to generate a first output signal having a first loop bandwidth using the control signal; a second VCO adapted to generate a second output signal having a second loop bandwidth using the control signal; and an output switch for selecting one of the first output signal and the second output signal and outputting the selected signal as the output signal of the RADAR.

According to embodiments of the invention, each of the first VCO and the second VCO may support 76 GHz-81 GHz spectrum.

According to embodiments of the invention, the first output signal may be suitable for detecting short-range targets located at a distance of 0 meters to 120 meters from the FMCW RADAR, and the second output signal may be suitable for detecting long-range targets located at a distance of 120 meters to 300 meters from the FMCW RADAR.

According to embodiments of the invention, the first VCO may include a first varactor with a first capacitance that may be adapted to support a first continuous bandwidth of at least 4000 MHz, and the second VCO may include a second varactor with capacitance that may be adapted to support a second continuous bandwidth of maximum 1000 MHz and a phase-noise of down to −105 dBc/Hz at 1 MHz offset.

According to embodiments of the invention, the second varactor may be 2 to 8 times smaller in physical size than the first varactor.

According to embodiments of the invention, the first VCO may be configured to have a loop bandwidth of 2 MHz, and the second VCO may be configured to have a loop bandwidth of 0.5 MHz.

According to embodiments of the invention, the feedback loop may include: a feedback divider for generating a feedback signal from the output signal of the RADAR; a phase detector to detect a phase and frequency difference between the reference signal and the feedback signal; and a loop filter connected to the phase detector, to filter out high frequency components form the signal provided by the phase detector to generate the control signal.

According to embodiments of the invention, the loop filter may be a dual mode loop filter that may be controlled to select a first mode suitable for activating the first VCO and a second mode for activating the second VCO.

According to embodiments of the invention, the first mode may have a first transfer function that may provide 300 KHz-1 MHz loop bandwidth and a phase-noise reduction of the overall PLL that may be smaller than −95 dBc/Hz at 1 MHz offsets at 80 GHz, and wherein the second mode may be configured to have a second transfer function that may provide 1 MHz-3 MHz loop bandwidth and a settling time of the wide chirping carrier that is at least 50 MHz/1 usec.

According to embodiments of the invention, the output switch may be switched every 1 to 50 frames.

According to embodiments of the invention, a dual mode phase locked loop (PLL) for a RADAR transmitter, may include: a phase detector to detect a phase and frequency of a reference signal; a loop filter connected to the phase detector, to filter out high frequency components form the signal provided by the phase detector; a first voltage-controlled oscillator (VCO) connected to the loop filter and adapted to generate a first output signal with a first loop bandwidth; a second VCO connected to the loop filter and adapted to generate a second output signal with a second loop bandwidth; and an output switch for transmitting one of the first output signal or the second output signal.

Embodiments of the invention may include a feedback divider for generating a feedback signal from the transmitted signal to be added to the reference signal.

According to embodiments of the invention, each of the first VCO and the second VCO may support 76 GHz-81 GHz spectrum.

According to embodiments of the invention, the first output signal may be suitable for detecting short-range targets, and the second output signal may be suitable for detecting long-range targets.

According to embodiments of the invention, the first VCO may include a first varactor with a first capacitance that may be adapted to support a first continuous bandwidth of at least 4000 MHz, and the second VCO may include a second varactor with capacitance adapted to support a second continuous bandwidth of maximum 1000 MHz and a phase-noise of down to −105 dBc/Hz at 1 MHz.

According to embodiments of the invention, the second varactor may be 2 to 8 times smaller in physical size than the first varactor.

According to embodiments of the invention, the first VCO may be configured to have a loop bandwidth of 2 MHz, and the second VCO may be configured to have a loop bandwidth of 0.5 MHz.

According to embodiments of the invention, the loop filter may be a dual mode loop filter that may be controlled to select a first mode suitable for activating the first VCO and a second mode for activating the second VCO.

According to embodiments of the invention, the first mode may have a first transfer function that provides 300 KHz-1 MHz loop bandwidth and a phase-noise reduction of the overall PLL to below −95 dBc/Hz at 1 MHz offsets at 80 GHz output frequency, and the second mode may have a second transfer function that provides 1 MHz-3 MHz loop bandwidth and settling time of the wide chirping carrier that is at least 50 MHz/1 usec.

According to embodiments of the invention, the output switch may be switched every 1 to 50 frames.

### BRIEF DESCRIPTION OF THE DRAWINGS

The subject matter regarded as the invention is particularly pointed out and distinctly claimed in the concluding portion of the specification. Embodiments of the invention, however, both as to organization and method of operation, together with objects, features and advantages thereof, may best be understood by reference to the following detailed description when read with the accompanied drawings. Embodiments of the invention are illustrated by way of example and not limitation in the figures of the accompanying drawings, in which like reference numerals indicate corresponding, analogous or similar elements, and in which:

FIG. 1 is a high-level schematic illustration of an FMCW RADAR transceiver, according to embodiments of the invention;

FIG. 2, is a high-level schematic illustration of a prior art single mode SR PLL for an FMCW RADAR transceiver;

FIG. 3 is a high-level schematic illustration of a prior art single mode LR PLL for an FMCW RADAR transceiver;

FIG. 4 is a high-level schematic illustration of a prior art SR and LR PLL for an FMCW RADAR transceiver;

FIG. 5 is a high-level schematic illustration of a prior art dual mode SR and LR PLL for an FMCW RADAR transceiver; and

FIG. 6 is a high-level schematic illustration of a dual mode PLL, according to embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention will be described. For purposes of explanation, specific configurations and details are set forth in order to provide a thorough understanding of the present invention. However, it will also be apparent to one skilled in the art that the present invention may be practiced without the specific details presented herein. Furthermore, well known features may be omitted or simplified in order not to obscure the present invention.

Although some embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device that manipulates and/or transforms data represented as physical (e.g., electronic) quantities within the computer's registers and/or memories into other data similarly represented as physical quantities within the computer's registers and/or memories or other information transitory or non-transitory or processor-readable storage medium that may store instructions, which when executed by the processor, cause the processor to execute operations and/or processes. Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term “set” when used herein may include one or more items unless otherwise stated. Unless explicitly stated, the method embodiments described herein are not constrained to a particular order or sequence. Additionally, some of the described method embodiments or elements thereof can occur or be performed in a different order from that described, simultaneously, at the same point in time, or concurrently.

FMCW RADAR systems may radiate continuous electromagnetic signals that are modulated in frequency or change in phase. The frequency of the transmitted electromagnetic signals may increase or decrease, or the phase may change periodically in time. The change of frequency or phase in the received echo signal may be delayed, and the target range may be derived from the frequency or phase differences between the transmitted and the received signals. Thus, FMCW radar may enable measurements of the target range and relative velocity. Typically, the frequency (or phase) of an FMCW radar signal is linearly modulated and the linear slopes of the waveform profile are referred to as chirps. A very common FMCW waveform profile includes a triangular profile featuring up-chirps and down-chirps, or a sawtooth profile featuring up-chirps and sharp down-chirps.

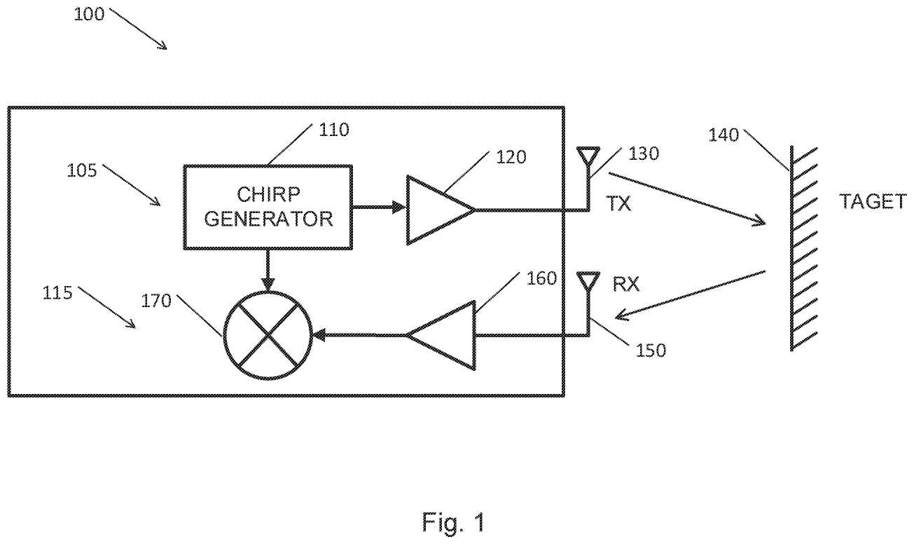

Reference is now made to FIG. 1 which depicts a high-level schematic illustration of an FMCW RADAR transceiver 100, according to embodiments of the invention. An FMCW RADAR transceiver 100 may include a transmitter 105 for transmitting electromagnetic signals, and a receiver 115 for receiving echo or reflected signal. Transmitter 105 may include chirp generator or synthesizer 110 that may generate signals having a desired waveform profile, e.g., a triangular profile including linear up-chirps and down-chirps or sawtooth profile featuring up-chirps and sharp down-chirps. A power amplifier 120 may amplify the signals generated by chirp generator 130 and feed the amplified signal to a transmit antenna 130. The transmitted electromagnetic signals may hit a target 140. Some of the transmitted electromagnetic signals may be reflected back from target 140 and picked by receive antenna 150. The received signals may be amplified by amplifier 160 and mixed or compared with the signal generated by chirp generator 110 by mixer 170. The frequency difference or phase differences between the received signal and the signal generated by chirp generator 110 may be related to the distance of target 140 from RADAR transceiver 100. Thus, the distance of target 140 may be obtained by signal processing methods such as a fast Fourier transform (FFT). The distance of target 140 from transceiver 100 may be determined based on the frequency or phase difference between the received and transmitted electromagnetic signals. Thus, a highly linear frequency or phase chirp may be required to provide high measurement accuracy.

According to embodiments of the invention chirp generator 110 may be or may include a dual mode PLL as disclosed herein. The dual mode PLL may generate the linear chirps. The overall performance of the FMCW radar system 100 may be highly affected by the performance and capabilities of the PLL. As will be explained herein, PLL design, and specifically design of a dual mode PLL for dual mode FMCW radar system 100 may involve challenging and partly conflicting requirements for the design of the dual mode PLL.

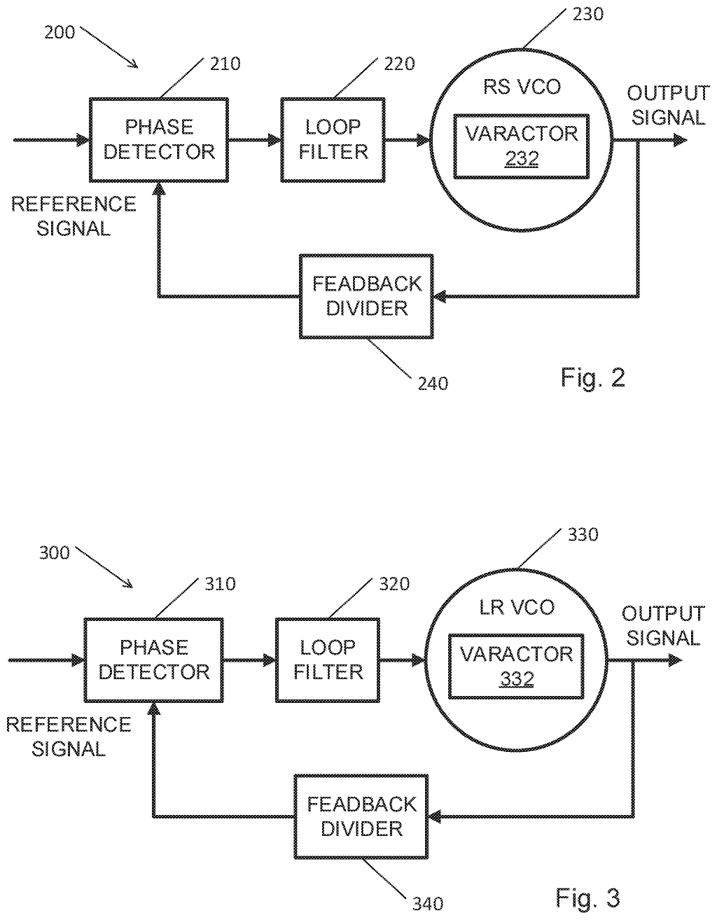

Reference is now made to FIG. 2 which depicts a high-level schematic illustration of a prior art single mode SR PLL 200 for an FMCW RADAR transceiver, and to FIG. 3 which depicts a high-level schematic illustration of a prior art single mode LR PLL 300 for an FMCW RADAR transceiver. SR PLL 200 may include phase detector (PD) 210, a loop filter (LF) 220, SR voltage-controlled-oscillator (VCO) 230 and a feedback divider 240. LR PLL 300 may include phase detector 310, a loop filter 320, LR VCO 330 and a feedback divider 340. While the high-level design of SR PLL 200 and LR PLL 300 may be similar, the design of the specific components may differ to support each detection range, as explain herein. The main function of phase detector 210, loop filter 220, SR VCO 230 and feedback divider 240 will be described herein below. The principal function of phase detector 310, loop filter 320, LR VCO 330 and feedback divider 340 is similar to corresponding components of SR PLL 200 and therefore will not be described in detail, only the differences will be highlighted.

SR VCO 230 may produce an output signal whose frequency varies with the voltage amplitude of the control signal provided by loop filter 220 over range of frequencies. SR VCO 230 may include a varactor diode 232 (also referred to as a varicap diode) that may be a junction diode designed to provide variable capacitance. The capacitance range of varactor diode 232 may determine the tuning range of SR VCO 230. Thus, varactor 232 may be the main device for changing the output frequency of PLL 200. Typical SR VCOs 230 are nonlinear with respect to the input frequency control signal (e.g., generated by phase detector 210) owing to nonlinear devices included in SR VCO 230, such as varactor diode 232. Therefore, SR PLL 200 may include a control system or a feedback loop, including for example phase detector 210, a loop filter 220 feedback divider 240, to compensate for the nonlinearity of SR VCO 230.

Phase detector 210 may obtain a reference signal, e.g., an accurate chirp FMCW signal generated by a direct digital frequency synthesizer (DDFS), and a feedback signal from feedback divider 240. Phase detector 210 may detect phase and/or frequency differences between the feedback signal and the reference signal and generate a control signal for a loop filter 220. Loop filter 220 may filter out (e.g. remove) high frequency components from the signal generated by phase detector 210, and feedback divider 240 may sample the output signal, divide the frequency of the output signal to generate a frequency divided signal, and provide the frequency divided signal as a feedback signal to phase detector 210.

The requirements and design of PLLs 200 and 300 may vary significantly depending on the detection range, e.g., the range of physical distances in which target 140 is detectable. For example, for SR detection, e.g., to detect targets 140 located within a distance of up to 120 meters from FMCW RADAR transceiver 100, a wide continuous bandwidth (BW) and fast chirp ramp may be required. On the contrary, LR detection, e.g., detection targets 140 located within a distance of 120 up to 300 meters from FMCW RADAR transceiver 100, requires best possible phase noise (e.g., a measure of the random fluctuations in the phase of the transmitted RF signal) and integrated non-linearity (INL, a measure of the linearity of the chirp of the transmitted RF signal) performance. As known, wide continuous bandwidth typically results in degraded phase noise and integrated non-linearity performance. Thus, the technical requirements for SR and LR detection contradict. Therefore, prior art VCOs 230 and 330 are typically optimized for either LR detection or SR detection.

For example, for SR detection, SR VCO 230 may provide wide continuous bandwidth. In order to enable that wide continuous bandwidth, SR VCO 230 may include varactor 232 with higher capacitance and hence larger physical dimensions or size (in comparison to VCO 330 adapted for LR detection). Additionally, loop filter 220 adapted for RS detection may support high charge-pump current and fast settling and tracking of the wide continuous bandwidth which is required when supporting fast chirp ramp, while compromising linearity, Sigma-delta-modulator (DSM) error-smoothing and phase noise.

On the contrary, for LR detection, LR VCO 330 may provide best possible phase noise and INL performance. To achieve the best possible phase noise and INL performance, the continuous bandwidth may be narrowed (in comparison to SR mode). Thus, LR VCO 330 adapted for LR detection may include small varactor 332 that can only support narrower continuous bandwidth, but provides best possible phase noise and INL performance.

Table 1 provides typical requirements from SR PLL 200 and LR PLL 300. As listed in Table 1, for SR detection, SR PLL 200 may provide continuous bandwidth of at least 4000 MHz (mega Hertz), phase noise of −90 dBc/Hz (decibels relative to the carrier signal at 1 MHz offset), and INL of 0.5%. In typical applications, the supported bands (e.g., the range of frequencies used by PLL 200) are 77-81 GHz (Giga Hertz). Those requirements typically imply a relatively large varactor 232 size, e.g., about four times bigger, or two to eight times bigger than the size of a varactor 332 for LR PLL 300, and a loop bandwidth of about 2 MHz or 1 MHz-3 MHz. Typically, the power consumption of SR PLL 200 is low relatively to LR PLL 300. For LR detection, LR PLL 300 may provide narrower continuous bandwidth relatively to SR PLL 200, e.g., of 1000 MHz. The phase noise, however, should be −105 dBc/Hz or lower, and the INL should be 0.1% or lower. In typical applications, the supported bands are 76-77 GHz. Those requirements typically enable using a relatively small varactor 332 size, e.g., about four times smaller or two to eight times smaller in physical dimensions (e.g., requires less semiconductor material and space) than the size of a varactor 232, and a loop bandwidth of about 0.5 MHz or 0.4-0.6 MHz. Typically, the power consumption of LR PLL 300 is high relatively to SR PLL 200.

TABLE 1
Example requirements from SR and LR PLLs.

| | | Short-Range | Long-Range |
|---|---|---|---|
| Requirements | Continuous BW [MHz] | 4000 | 1000 |
| | Phase noise [dBc/Hz] | −90 | −105 |
| | Supported bands [GHz] | 77-81 | 76-77 |
| | INL | 0.5% | 0.1% |
| PLL | Varactor size | ~4X | X |
| Architecture | Loop BW [MHz] | ~2 | ~0.5 |
| | Power | Low | Higher |

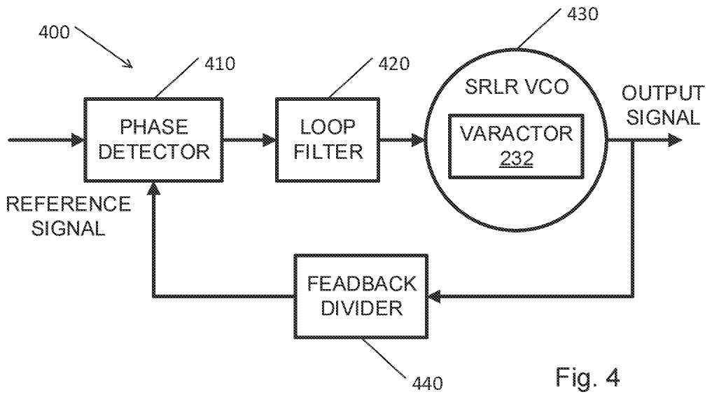

Current solutions for providing both SR and LR detection may include designing a single PLL that would be a compromise between the contradicting requirements. FIG. 4 presents a high-level schematic illustration of such a single PLL 400 for both ranges. Long range and short range (LRSR) PLL 400 may include phase detector 410, loop filter 420, VCO 430 and feedback divider 440, whose function is generally similar to phase detector 210, loop filter 220, VCO 230 and feedback divider 240, respectively. While the high-level design of LRSR PLL 400 may be similar to SR PLL 200 and LR PLL 300, the design of the specific components may differ to support wider detection range, as explain herein.

Table 2 provides typical requirements from SR PLL 200, LR PLL 300 and LRSR PLL 400. As can be seen in Table 2, LRSR PLL 400 is a trade-off between the contradicting requirements of for SR detection and LR detection. Unfortunately, this results in degraded performances in both ranges. LRSR PLL 400 may provide continuous bandwidth of 1000 to 4000 MHz, depending on the mode of operation. The phase noise of LRSR PLL 400 may be only −90 dBc/Hz. and the INL may be only 0.5%, both are not optimal for detecting targets at the LR. The supported bands may be 76-81 GHz to support detection at both SR and LR. The large continuous bandwidth of at least 4,000 MHz required for the SR detection implies a relatively large varactor 432 size, e.g., about four times bigger than the size of a varactor 332 for LR PLL 300, and similar varactor size to SR PLL 200. Typically, the power consumption of SRLR PLL 400 is medium, somewhere in between SR PLL 200 and LR PLL 300. Thus, the combined SRLR PLL 400 does not meet specifications of both SR and LR, and thus SRLR PLL 400 provides degraded SR and LR performances. For example, as indicated in Table 2 phase-noise performance and integrated non-linearity may not be good enough for long-range detection.

TABLE 2
Example requirements from SR, LR, and SRLR PLLs.

| | | | | Short and |
|---|---|---|---|---|
| | | Short-Range | Long-Range | Long Range |
| Requirements | Continuous BW [MHz] | 4000 | 1000 | 1000-4000 |
| | Phase noise [dBc/Hz] | −90 | −105 | −90 |
| | Supported bands [GHz] | 77-81 | 76-77 | 76-81 |
| | INL | 0.5% | 0.1% | 0.5% |
| PLL | Varactor size | ~4X | X | ~4X |
| Architecture | Loop BW [MHz] | ~2 | ~0.5 | ~1 |
| | Power | Low | Higher | Medium |

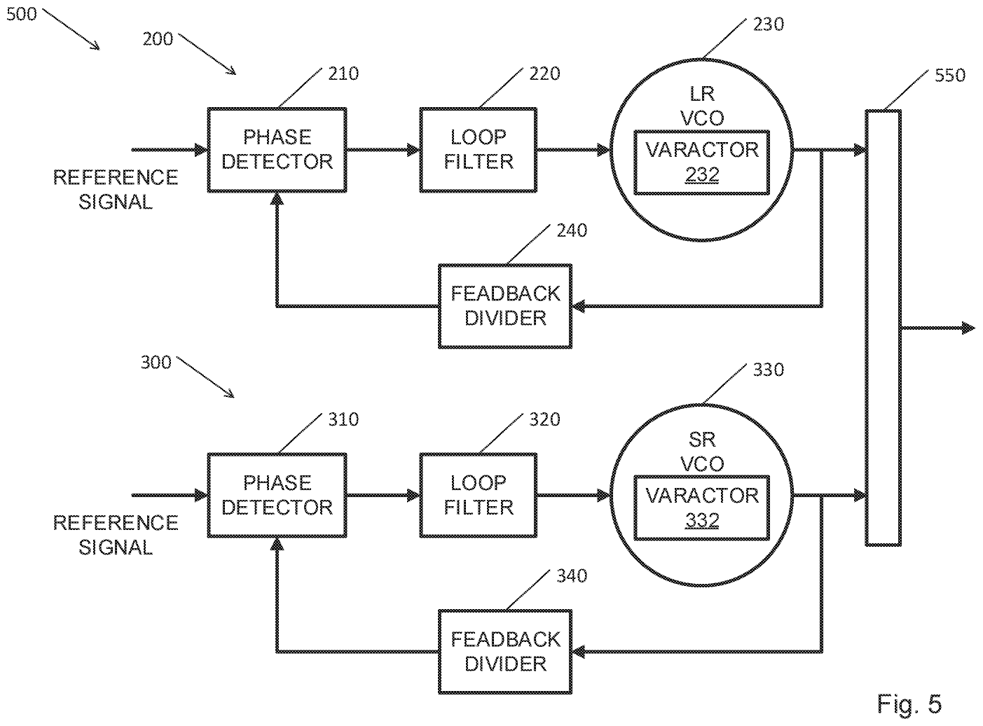

Another solution for combined SL and LR PLL is provided in FIG. 5. FIG. 5 depicts a high-level schematic illustration of a prior art dual mode SR and LR PLL 500 for an FMCW RADAR transceiver. The solution presented in FIG. 5 includes two PLLs, SR PLL 200 and LR PLL 300, where the output signal is selected by switching output switch 550 from one setting to another. While this solution provides good quality detection in both ranges, it requires two PLLs, which results in increased silicon size and external loop-filter components (on-printed circuit board (PCB) resistors and capacitors) and results in higher costs.

According to embodiments of the invention, a dual mode PLL may be provided, with only minimal duplication of hardware. Thus, embodiments of the invention may provide a dual mode PLL that is optimized for both SR and LR detection similarly to prior art dual mode SR and LR PLL 500, but using less hardware, and therefore requires less silicon size and is less costly comparing to prior art dual mode SR and LR PLL 500.

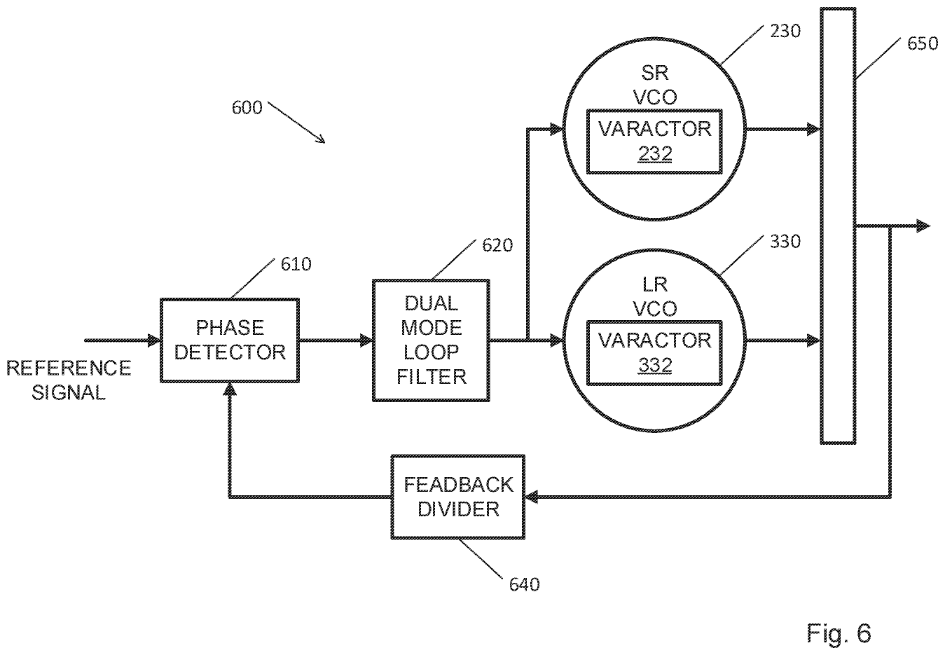

Reference is now made to FIG. 6, which depicts a high-level schematic illustration of dual mode PLL 600, according to embodiments of the invention. Dual mode PLL 600 may include phase detector 610, dual mode loop filter 620, SR VCO 230, LR VCO 330 and feedback divider 640. Thus, dual mode PLL 600 may include a single feedback loop or control system and two VCOs, SR VCO 230 adapted to or optimized for detecting targets in the SR and LR VCO 330 adapted to or optimized for detecting targets in the LR. While some embodiments use one single feedback loop or control system, other embodiments may use more than one feedback loop or control system. A dual mode loop filter 620 may have two modes of operation to support SR and LR. Thus, dual mode PLL 600 may provide optimized SR and LR detection, with minimal duplication of hardware. Dual mode PLL 600 may provide better performances in both ranges comparing to LRSR PLL 400, with only slightly more hardware, and dual mode PLL 600 may provide similar performance as prior art dual mode SR and LR PLL 500, with less hardware.

Each of SR VCO 230 and LR VCO 330 may produce an output signal whose frequency varies with the voltage amplitude of the control signal provided by dual mode loop filter 620 over range of frequencies. In some embodiments, each of SR VCO 230 and LR VCO 330 may be activated and deactivated alternately. e.g., when SR VCO 230 is activated LR VCO 330 is deactivated and when LR VCO 330 is activated, SR VCO 230 is deactivated. The signal provided by SR VCO 230 and LR VCO 330 may be provided to output switch 650. Thus, an output signal may be selected by switching output switch 650 from one setting to another. In some embodiments, switching output switch 650 may be coordinated with activating and deactivating SR VCO 230 and LR VCO 330 and with selecting SR or LR mode at dual mode loop filter 620. Thus, when working in SR mode, SR VCO 230 may be activated, LR VCO 330 may be deactivated, dual mode loop filter 620 may be configured to operate at SR mode, and output switch 650 may be configured to select the signal provided by SR VCO 230 to be the output signal. Similarly, when working in LR mode, LR VCO 330 may be activated, SR VCO 230 may be deactivated, dual mode loop filter 620 may be configured to operate at LR mode, and output switch 650 may be configured to select the signal provided by LR VCO 330 to be the output signal. In some embodiments, output switch 650 may be switched or operated (e.g. from one setting to another to select the currently un-selected one of the output signals and un-select the second, currently selected, output signal) every 1 to 50 frames of the FMCW RADAR, wherein a frame may include one or more complete chirp ramps and possibly some idle time. In some embodiments, however, SR or LR modes may be selected for longer periods.

SR VCO 230 may include varactor 232, adapted for RS detection, and LR VCO 330 may include varactor 332, adapted for LS detection. Varactors 232 and 332 may be the main device for changing the output frequency of dual mode PLL 600 and may determine the tuning range of SR VCO 230 and LR VCO 330, respectively. As the range of output frequencies (the continuous bandwidth) required for SR detection is larger than the range of output frequencies required for LR detection, varactor 232 may be larger in size comparing to varactor 332. For example, the size of varactor 332 may be about four times (e.g., 2-8 times) smaller than the size of varactor 232 (smaller in physical dimensions e.g., requires less semiconductor material and space). This may result in degraded phase-noise and INL performance that is acceptable for SR mode. On the other hand, varactor 332 may provide a much narrower continuous bandwidth, be a lot smaller in physical dimensions) than varactor 232, and provide improved phase-noise and INL performance that is required for LR mode.

Typical VCOs 230 and 330 may be nonlinear with respect to the input frequency control signal owing to nonlinear devices included in VCOs 230 and 330, such as varactor diodes 232 and 332. Therefore, dual mode PLL 600 may include a control system or a feedback loop, including for example phase detector 610, a dual mode loop filter 620 feedback divider 640, to compensate for the nonlinearities of SR VCO 230 and LR VCO 330.

Phase detector 610 may obtain a reference signal, e.g., an accurate chirp FMCW signal generated by a direct digital frequency synthesizer (DDFS), and a feedback signal from feedback divider 640. Phase detector 610 may detect phase and/or frequency differences between the feedback signal and the reference signal to generate a control signal for dual mode loop filter 620.

Dual mode loop filter 620 may filter out high frequency components from the signal generated by phase detector 610, and feedback divider 640 may sample the output signal, divide the frequency of the output signal to generate a frequency divided signal, and provide the frequency divided signal as a feedback signal to phase detector 610.

Dual mode loop filter 620 may be controlled to select a SR mode suitable for activating RS VCO 230 or a LR mode for activating LR VCO 330. Dual mode loop filter 620 may have configurable loop bandwidth, for example by using internal resistor and charge-pump current. When operating in SR mode, dual mode loop filter 620 may support high charge-pump current and passive component configuration to provide fast settling and tracking of the wide bandwidth which is required when supporting fast chirp ramp, while compromising linearity, DSM error smoothing and phase noise. When operating in LR mode, dual mode loop filter 620 may support narrow filter passive configuration, e.g., passive elements and charge pump currents, to provide best phase noise (e.g., loop noise rejection), best linearity for narrow bandwidth chirps while smoothing of DSM dithering and loop phase errors. For example, in the LR mode, dual mode loop filter 620 may have a transfer function that provides 300 KHz-1 MHz, or 0.5 MHz loop bandwidth and a phase-noise reduction of dual mode PLL 600 that is smaller than −95 dBc/Hz at 1 MHz offsets at 80 GHz, and in the SR mode dual mode loop filter 620 may have a transfer function that provides 1 MHz-3 MHz or 2 MHz loop bandwidth and a settling time of the wide chirping carrier that is at least 50 MHz/1 usec.

According to some embodiments, both SR VCO 230 and LR VCO 330 may support the entire 76-81 GHz spectrum, which may enable both SR and LR modes to use entire available spectrum for FMCW RADAR systems.

Table 3 provides typical requirements from SR PLL 200, LR PLL 300, LRSR PLL 400 and dual mode PLL 600. As can be seen in Table 3, dual mode PLL 600 provides optimal performances for SR detection and LR detection, despite the contradicting requirements for these two ranges. Dual mode PLL 600 may provide continuous bandwidth of 1000 MHz or at least 4000 MHz, depending on the mode of operation, e.g., depending on which of VCOs 230 and 330 is activated and in combination with the mode of dual mode loop filter 620. The phase noise of dual mode PLL 600 may be as low as −105 dBc/Hz, and the INL may be 0.1%, both meeting the requirements for detecting targets at the LR. The supported bands may be 76-81 GHz at both SR and LR. Typically, the power consumption of a dual mode PLL 600 is medium, somewhere in between SR PLL 200 and LR PLL 300. Thus, dual mode PLL 600 meets specifications of both SR and LR, and provides the required SR and LR performances.

TABLE 3
Example requirements from SR LR, SRLR, and dual mode PLLs.

| | | | | Prior art | | |
|---|---|---|---|---|---|---|
| | | | | Short and | Dual mode | |
| | | Short-Range | Long-Range | Long range | PLL | |
| Requirements | Continuous BW [MHz] | 4000 | 1000 | 1000-4000 | 1000 | (LR) |
| | | | | | 4000 | (SR) |
| | Phase noise [dBc/Hz] | −90 | −105 | −90 | −105 | (LR) |
| | Supported bands [GHz] | 77-81 | 76-77 | 76-81 | 76-81 | |
| | INL | 0.5% | 0.1% | 0.5% | 0.1 | (LR) |

| | | | | | |
|---|---|---|---|---|---|
| PLL | Varactor size | ~4X | X | ~4X | ~4X, X |
| Architecture | Loop BW [MHz] | ~2 | ~0.5 | ~1 | Configurable: |
| | | | | | 0.5-2 |
| | Power | Low | High | Medium | Selectable |

For the processes and/or methods disclosed, the functions performed in the processes and methods may be implemented in differing order as may be indicated by context. Furthermore, the outlined steps and operations are only provided as examples, and some of the steps and operations may be optional, combined into fewer steps and operations, or expanded into additional steps and operations.

The present disclosure is not to be limited in terms of the particular embodiments described in this application, which are intended as illustrations of various aspects. Many modifications and variations can be made without departing from its scope. Functionally equivalent methods and apparatuses within the scope of the disclosure, in addition to those enumerated, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is also to be understood that the terminology used in this disclosure is for the purpose of describing particular embodiments only, and is not intended to be limiting.

This disclosure may sometimes illustrate different components contained within, or connected with, different other components. Such depicted architectures are merely exemplary, and many other architectures can be implemented which achieve the same or similar functionality.

1. A phase locked loop (PLL) for a long-range and short-range frequency-modulated carrier-frequency (FMCW) RADAR system, comprising:
a single feedback loop for generating a control signal based on differences between an output signal of the RADAR and a reference signal;
a first voltage-controlled oscillator (VCO) adapted to generate a first output signal having a first loop bandwidth using the control signal;
a second VCO adapted to generate a second output signal having a second loop bandwidth using the control signal; and
an output switch for selecting one of the first output signal and the second output signal and outputting the selected signal as the output signal of the RADAR.

2. The system of claim 1, wherein each of the first VCO and the second VCO supports 76 GHz-81 GHz spectrum.

3. The system of claim 1, wherein the first output signal is suitable for detecting short-range targets located at a distance of 0 meters to 120 meters from the FMCW RADAR, and the second output signal is suitable for detecting long-range targets located at a distance of 120 meters to 300 meters from the FMCW RADAR.

4. The system of claim 1, wherein the first VCO comprises a first varactor with a first capacitance that is adapted to support a first continuous bandwidth of at least 4000 MHz, and wherein the second VCO comprises a second varactor with capacitance adapted to support a second continuous bandwidth of maximum 1000 MHz and a phase-noise of down to −105 dBc/Hz at 1 MHz offset.

5. System of claim 4, wherein the second varactor is 2 to 8 times smaller in physical size than the first varactor.

6. The system of claim 1, wherein the first VCO is configured to have a loop bandwidth of 2 MHz, and the second VCO is configured to have a loop bandwidth of 0.5 MHz.

7. The system of claim 1, wherein the feedback loop comprises:
a feedback divider for generating a feedback signal from the output signal of the RADAR;
a phase detector to detect a phase and frequency difference between the reference signal and the feedback signal; and
a loop filter connected to the phase detector, to filter out high frequency components form the signal provided by the phase detector to generate the control signal.

8. The system of claim 7, wherein the loop filter is a dual mode loop filter that is controlled to select a first mode suitable for activating the first VCO and a second mode for activating the second VCO.

9. The system of claim 8, wherein the first mode has a first transfer function that provides 300 KHz-1 MHz loop bandwidth and a phase-noise reduction of the overall PLL that is smaller than −95 dBc/Hz at 1 MHz offsets at 80 GHz, and wherein the second mode is configured to have a second transfer function that provides 1 MHz-3 MHz loop bandwidth and a settling time of the wide chirping carrier that is at least 50 MHz/1 usec.

10. The system of claim 1, wherein the output switch is switched every 1 to 50 frames.

11. A dual mode phase locked loop (PLL) for a RADAR transmitter, comprising:
a phase detector to detect a phase and frequency of a reference signal;
a loop filter connected to the phase detector, to filter out high frequency components form the signal provided by the phase detector;
a first voltage-controlled oscillator (VCO) connected to the loop filter and adapted to generate a first output signal with a first loop bandwidth;
a second VCO connected to the loop filter and adapted to generate a second output signal with a second loop bandwidth; and
an output switch for transmitting one of the first output signal or the second output signal.

12. The system of claim 11, comprising:
a feedback divider for generating a feedback signal from the transmitted signal to be added to the reference signal.

13. The system of claim 11, wherein each of the first VCO and the second VCO supports 76 GHz-81 GHz spectrum.

14. The system of claim 11, wherein the first output signal is suitable for detecting short-range targets, and the second output signal is suitable for detecting long-range targets.

15. The system of claim 11, wherein the first VCO comprises a first varactor with a first capacitance that is adapted to support a first continuous bandwidth of at least 4000 MHz, and wherein the second VCO comprises a second varactor with capacitance adapted to support a second continuous bandwidth of maximum 1000 MHz and a phase-noise of down to −105 dBc/Hz at 1 MHz.

16. System of claim 15, wherein the second varactor is 2 to 8 times smaller in physical size than the first varactor.

17. The system of claim 11, wherein the first VCO is configured to have a loop bandwidth of 2 MHz, and the second VCO is configured to have a loop bandwidth of 0.5 MHz.

18. The system of claim 11, wherein the loop filter is a dual mode loop filter that is controlled to select a first mode suitable for activating the first VCO and a second mode for activating the second VCO.

19. The system of claim 19, wherein the first mode has a first transfer function that provides 300 KHz-1 MHz loop bandwidth and a phase-noise reduction of the overall PLL to below −95 dBc/Hz at 1 MHz offsets at 80 GHz output frequency, and wherein the second mode has a second transfer function that provides 1 MHz-3 MHz loop bandwidth and settling time of the wide chirping carrier that is at least 50 MHz/1 usec.

20. The system of claim 11, wherein the output switch is switched every 1 to 50 frames.
